(19) United States
(12) Patent Application Publication
(10) Pub. No.: US 2026/0262189 A1
(43) Pub. Date: Sep. 3, 2026

(54) COOLING DEVICE FOR A SYSTEM FOR COOLING ELECTRONIC DEVICES, AND COOLING METHOD

(71) Applicant: VALEO SYSTEMES THERMIQUES, La Verriere (FR)

(72) Inventors: Michael LISSNER, La Verriere (FR); Yvan LECHAT, La Verriere (FR); Arnaud DEVIENNE, La Verriere (FR); Luc DESTRO, La Verriere (FR); Rachid EL-ISSI, La Verriere (FR); Lionel FAURE, La Verriere (FR); Herve BOURGEAIS, La Verriere (FR); Yoann THUILLIER, La Verriere (FR); Alexis DE-LAPLANE, La Verriere (FR); Carlos RODRIGO, Zaragoza (ES)

(73) Assignee: VALEO SYSTEMES THERMIQUES, La Verriere (FR)

(21) Appl. No.: 19/163,574

(22) PCT Filed: Feb. 28, 2024
(86) PCT No.: PCT/EP2024/055132

§ 371 Date: Oct. 22, 2025

(30) Foreign Application Priority Data
Mar. 9, 2023 (FR) FR2302188

(51) Int. Cl. H05K 7/20

(52) U.S. Cl. CPC H05K 7/20236; H05K 7/20254; H05K 7/20263; H05K 7/20272; H05K 7/20772

(57) ABSTRACT

A cooling device for a system for cooling electronic components partially immersed in a dielectric fluid, including a first heat exchanger. The first heat exchanger is configured to be partially immersed in the dielectric fluid and includes a first circuit for a first heat-transfer fluid. The cooling device also includes a second heat exchanger configured to be in contact with a part of the electronic components, the second heat exchanger being fluidically connected to the first heat exchanger in such a way that the first heat exchanger and the second heat exchanger together form a second circuit for a second heat-transfer fluid.

### TECHNICAL FIELD

The present invention relates to a cooling device and to a cooling system for cooling electronic devices. The present invention also relates to a method for cooling an electronic device.

### BACKGROUND OF THE INVENTION

Servers used for data processing (commonly referred to as information technology or IT) generally comprise printed circuit boards (PCBs) on which are arranged electronic components such as integrated circuits, which may include central processing units (CPUs), random access memory (RAM), etc. All of these electronic components or devices generate heat when they are used. In order to maintain the contents at an optimal temperature to maximize computer performance, it is essential to discharge the heat thus generated and/or to cool the components in question.

In general, electronic components or devices used in servers are air-cooled. A heat sink with fins or similar elements is generally used to discharge heat to the surrounding air. Such a heat sink is thus placed in contact with the surface of the electronic chip. This contact may be direct or may be achieved using a thermal interface material between the two components. In addition to the heat sink, one or more fans may be used to draw in and circulate air so as to discharge heat from the heat sink. Such a heat sink may be used in combination with cooling provided by the server installation, such as air conditioning. However, this cooling method is not particularly effective. It also has a high running cost and requires very large spaces to manage the air used for cooling.

Liquid cooling is an alternative to air cooling. In some cases, liquid cooling allows for more efficient heat transfer from electronic components or devices, resulting in greater cooling power. These liquids are, for example, dielectric fluids, mineral oil or water. Liquids having a high specific heat capacity are particularly advantageous.

### SUMMARY OF THE INVENTION

One of the aims of the present invention is therefore to propose a cooling device and a cooling system for cooling electronic devices which makes it possible to adapt the cooling power to each of the components to be cooled and which also makes it possible to facilitate the circuit for thermal fluids intended to circulate through the cooling device.

To this end, the invention relates to a cooling device for a cooling system for cooling electronic components partially immersed in a dielectric fluid, comprising a first heat exchanger, the cooling device being characterized in that the first heat exchanger, notably a plate heat exchanger, is configured to be partially immersed in the dielectric fluid, said first heat exchanger comprising a first circuit for a first heat transfer fluid, and characterized in that the cooling device includes a second heat exchanger configured to be in contact with a portion of the electronic components, said second heat exchanger being fluidically connected to the first heat exchanger in such a way that the first heat exchanger and the second heat exchanger together form a second circuit for a second heat transfer fluid.

Such a cooling device makes it possible to cool several different elements or several different circuits using a single source, thus simplifying the circuit. In addition, the cooling power may be adapted to each of the components to be cooled.

According to an example of an embodiment, the first heat exchanger further comprises a cooling plate configured to be immersed in the dielectric fluid and thermally coupled to the first heat exchanger such that the heat produced by the immersed electrical components and transferred via the dielectric fluid to the cooling plate can be discharged via the first heat exchanger.

According to an example of an embodiment, the first circuit for the first heat transfer fluid includes a fluidic connection between the first heat exchanger and the cooling plate. Moreover, the cooling plate includes a portion of the first circuit for the first heat transfer fluid such that the first heat transfer fluid can circulate inside the cooling plate.

According to an example of an embodiment, the fluidic connection between the first heat exchanger and the cooling plate is arranged inside the first heat exchanger and the cooling plate.

According to another example of an embodiment, the fluidic connection is positioned outside said first heat exchanger and the cooling plate.

According to an example of an embodiment, the second heat exchanger includes at least one extension with an end configured to be bathed in the dielectric fluid contained in the receptacle.

Furthermore, an attachment interface may be attached to the first heat exchanger.

Moreover, the cooling plate may be attached to this attachment interface.

According to another example of an embodiment, a thermal interface is arranged between the first heat exchanger and the cooling plate.

According to an example of an embodiment, the first heat exchanger and/or the second heat exchanger is/are manufactured by additive manufacturing.

The invention also relates to a cooling system that uses such a cooling device, in particular for cooling computer servers. However, this cooling system may be applied to the cooling of other electronic components and devices.

According to an example of an embodiment, the cooling system includes a receptacle intended to contain electronic devices and/or electronic components and dielectric fluid; and the electronic devices and the electronic components are intended to be bathed in the dielectric fluid and the cooling system includes a cooling device as described above, the first heat exchanger of said cooling device being intended to be bathed at least partially in the dielectric fluid contained in the receptacle.

According to another example of an embodiment, the cooling system comprises a movement means for setting a fluid in motion, such as a pump or a propeller arranged inside the receptacle.

Furthermore, said movement means is configured to circulate the dielectric fluid contained in the receptacle.

Moreover, said movement means is in particular immersed in the dielectric fluid contained in the receptacle.

According to another example of an embodiment, the second heat exchanger of the cooling device is coupled to at least one of the electronic components intended to be bathed in the dielectric fluid.

The invention also relates to a cooling method for cooling an electronic device which comprises the following steps:
evaporation of the second heat transfer fluid in a second heat exchanger;
condensation of the second heat transfer fluid in the first heat exchanger.

According to a variant, the cooling method further comprises an additional step in which the first heat transfer fluid circulates inside the cooling plate immersed in the dielectric fluid, the cooling plate being thermally coupled to the first heat exchanger such that heat transfer occurs between the first heat transfer fluid and the dielectric fluid.

According to a variant, the second heat transfer fluid circulates inside the extension of the second heat exchanger, one end of the extension being bathed in the dielectric fluid.

According to a variant, the cooling method further comprises an additional step in which the dielectric fluid circulates around a set of electronic components in order to cool them by bubbling.

### BRIEF DESCRIPTION OF THE DRAWINGS

Further advantages and features will become apparent on reading the description of several illustrative but non-limiting examples of the present invention, together with the appended drawings in which:

FIG. 1 schematically depicts a cooling system for cooling an electronic device;

FIG. 2 schematically depicts a first embodiment of a cooling device of the cooling system of FIG. 1;

FIG. 3 schematically depicts a second embodiment of a cooling device of the cooling system of FIG. 1;

FIG. 4 schematically depicts a variant of the cooling system for cooling an electronic device of FIG. 1.

### DETAILED DESCRIPTION OF THE INVENTION

In these figures, identical elements have the same reference numbers.

The following embodiments are examples. Although the description refers to one or more embodiments, this does not necessarily mean that each reference relates to the same embodiment, or that the features only apply to a single embodiment. Individual features of different embodiments may also be combined or interchanged to provide other embodiments.

In the present description, certain elements or parameters may be indexed, for example first element or second element and first parameter and second parameter or first criterion and second criterion, etc. In this case, this is simply indexing to differentiate and designate elements or parameters or criteria that are similar but not identical. This indexing does not imply priority of one element, parameter or criterion with respect to another and such denominations may easily be interchanged without departing from the scope of the present description. Neither does this indexing imply any chronological order for example in assessing any given criterion.

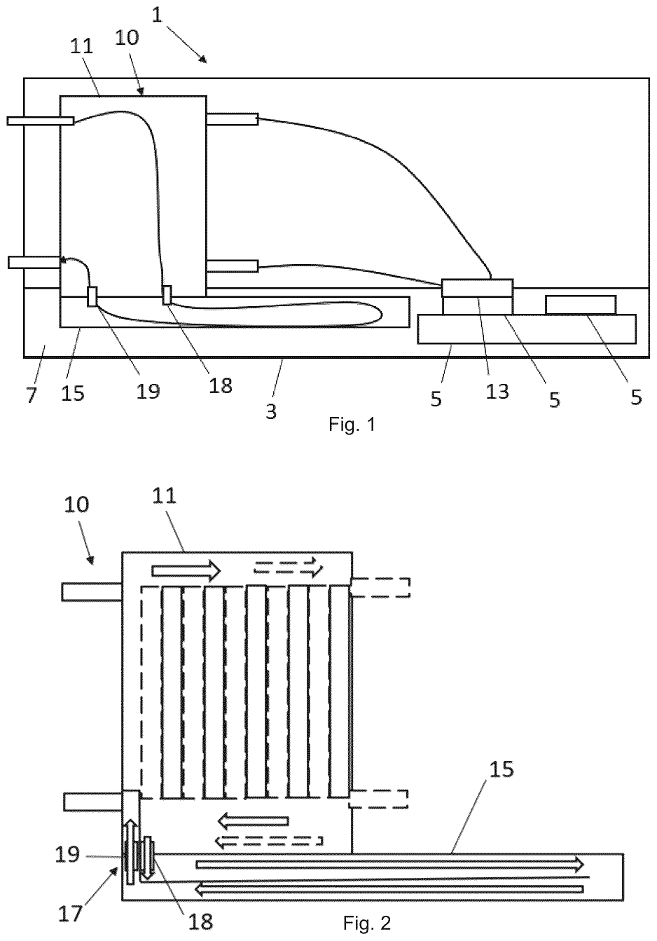

Reference will first be made to FIG. 1, which schematically shows a system 1 for cooling electronic components 5. This cooling system 1 comprises a receptacle 3 intended to contain electronic devices 5 and/or electronic components 5 as well as dielectric fluid 7. The electronic devices 5 and the electronic components 5, which tend to emit heat during operation, are immersed in the dielectric fluid 7 in order to be cooled by the latter.

The electronic components 5 are, for example, computer components such as graphics processing units (GPUs) or central processing units (CPUs) or switching components. These electronic components 5 are typically used in servers at a data center. Since these components 5 are very small in size, a large number of these components 5 may be arranged in the servers. However, this compact arrangement means that a greater amount of heat is generated per component, which needs to be dissipated efficiently. In addition, cooling requirements may vary from one type of electronic component to another.

At the heart of the cooling system 1 is a cooling device 10 comprising a first heat exchanger 11. This first heat exchanger 11 is in particular a plate heat exchanger which is partially immersed in the dielectric fluid 7. This first heat exchanger 11 comprises a first circuit for a first heat transfer fluid. This first heat transfer fluid may in particular be in the form of a water-based cooling liquid, a dielectric fluid, or a coolant.

The cooling device 10 further comprises a second heat exchanger 13 configured to be in contact with a portion of the electronic components 5. The second heat exchanger 13 is fluidically connected to the first heat exchanger 11 such that the first heat exchanger 11 and the second heat exchanger 13 together form a second circuit for a second heat transfer fluid.

This second heat transfer fluid may in particular be in the form of a two-phase fluid. The second heat transfer fluid is therefore caused to change state while it is circulating in the second circuit. More particularly, the two-phase second heat transfer fluid may undergo evaporation inside the second heat exchanger 13, in other words at least part of the second heat transfer fluid changes from the liquid state to the gaseous state, while this same two-phase second heat transfer fluid may undergo condensation inside the first heat exchanger 11, in other words at least part of the second heat transfer fluid changes from the gaseous state to the liquid state.

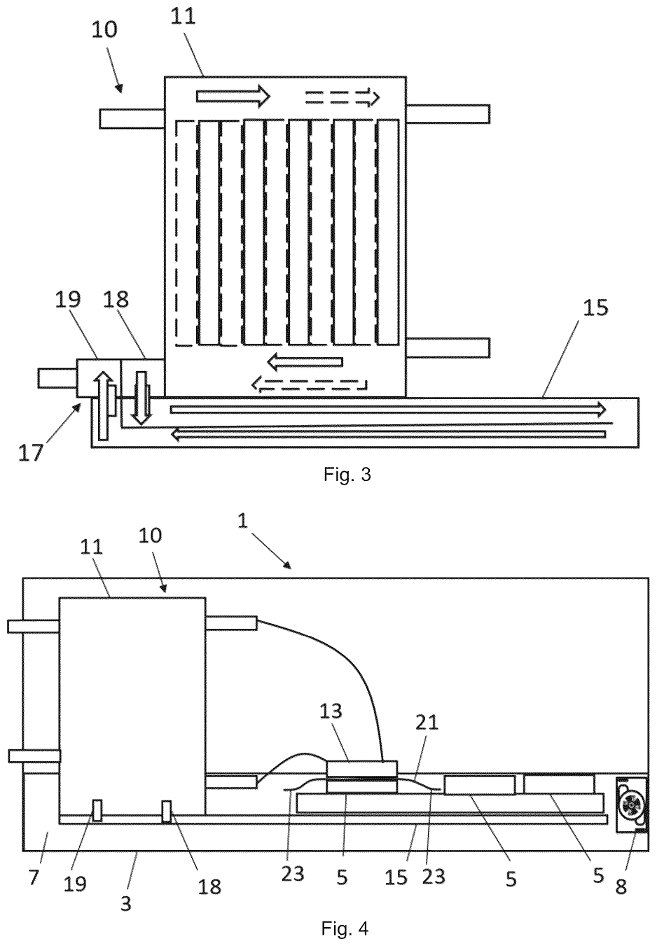

More particularly, the stack of plates in the first heat exchanger 11 delimits, on the one hand, at least a portion of the first circuit for the first heat transfer fluid and, on the other hand, at least a portion of the second circuit for the second heat transfer fluid, this being shown in particular in FIG. 2 and FIG. 3.

In these figures, the circulation of the first heat transfer fluid in the first circuit partially delimited by the first heat exchanger 11 is represented by arrows in solid lines while the circulation of the second heat transfer fluid in the second circuit partially delimited by the first heat exchanger 11 is represented by arrows in dotted lines. There is therefore heat exchange between the first heat transfer fluid and the second heat transfer fluid in the stack of plates in this first heat exchanger 11.

The second heat transfer fluid therefore circulates, on the one hand, in the portion of the second circuit partially delimited by the first heat exchanger 11, where the second heat transfer fluid undergoes heat exchange with the first heat transfer fluid, and it circulates on the other hand in the portion of the second circuit partially delimited by the second heat exchanger 13. Furthermore, the second heat exchanger 13 is configured to be thermally coupled to an electronic device comprising electronic components 5 immersed in the dielectric fluid 7. Thus, the second heat exchanger 13 serves to discharge the heat emitted by the electronic components 5 of the electronic device to which it is coupled.

Optionally, the cooling device 10 may comprise a cooling plate 15 which is immersed in the dielectric fluid 7. This cooling plate 15 is then thermally coupled to the first heat exchanger 11 such that the heat produced by the immersed electrical components 5 and transferred via the dielectric fluid 7 to the cooling plate 15 can be discharged via the first heat exchanger 11. Such a cooling plate makes it possible to further regulate the temperature of the dielectric fluid 7 contained in the receptacle 3.

In general, the surface area of the cooling plate 15 is between 40% and 80% of the surface area inside the receptacle 3. According to one embodiment, the surface area of the cooling plate 15 corresponds to 60% of the surface area inside the receptacle 3.

The cooling plate 15 may in particular be attached to the first heat exchanger 11 by brazing. Rigidly securing the cooling plate 15 to the first heat exchanger 11 can make it possible to reinforce the structure of the cooling device 10. This also makes it possible to ensure sealing of the cooling device 10.

According to another embodiment, an attachment interface may be attached to the first heat exchanger 11. The cooling plate 15 is then attached to this attachment interface. Using an attachment plate between the heat exchanger and the cooling plate 15 allows greater freedom in the arrangement of the heat exchanger and the cooling plate 15.

Other means of attaching the cooling plate 15 to the first heat exchanger 11 may be envisaged.

According to a first embodiment, the first circuit for the first heat transfer fluid includes a fluidic connection 17 between the first heat exchanger 11 and the cooling plate 15. In this first embodiment, the cooling plate 15 then includes a portion of the first circuit for the first heat transfer fluid such that the first heat transfer fluid can circulate inside the cooling plate. This is shown in particular by the arrows in solid lines in FIG. 2 and FIG. 3. In this first embodiment, there is therefore heat exchange between the first heat transfer fluid and the dielectric fluid 7 via the cooling plate 15.

In this same embodiment, the fluidic connection 17 between the first heat exchanger 11 and the cooling plate 15 is arranged inside the first heat exchanger 11 and the cooling plate 15 in order to allow the first heat transfer fluid to circulate between these two elements. This embodiment is shown in particular in FIG. 2 and FIG. 3.

As shown in FIG. 2 and FIG. 3, the fluidic connection 17 comprises in particular an inlet 18 and an outlet 19. The inlet 18 allows the first heat transfer fluid to circulate from the first heat exchanger 11 to the cooling plate 15 while the outlet 19 allows the first heat transfer fluid to circulate from the cooling plate 15 to the first heat exchanger 11.

The first circuit therefore allows the first heat transfer fluid to circulate inside the first heat exchanger 11 to ensure heat exchange with the second heat transfer fluid, and also inside the cooling plate 15 to make it possible to cool the dielectric fluid 7 in which the cooling plate 15 is immersed.

In the first variant of this first embodiment illustrated in FIG. 2, the fluidic connection 17 is arranged inside said first heat exchanger 11 and the cooling plate 15. This variant has the advantage of being very compact.

In the second variant of this first embodiment illustrated in FIG. 3, the fluidic connection 17 is positioned outside said first heat exchanger 11 and the cooling plate. This variant has the advantage of being easier to manufacture than the first variant described above.

In some embodiments, the heat transfer fluid circuit in said cooling plate 15 has at least two passes, and a bypass device, active or passive, forming a fluidic connection between the two passes, the bypass device being configured to open or close the connection between the two passes to reduce the fluid circuit by bypassing a portion of said circuit.

Advantageously, the surface area for exchange of the cooling plate 15 is minimized or not minimized, which has the effect of modulating the power. In other words, the idea is to prevent the fluid from circulating in a portion of the plate so as not to cool the bubbling bath more than necessary.

According to a second embodiment, the first heat transfer fluid does not circulate inside the cooling plate 15: a temperature gradient is created within the cooling plate 15 purely by conduction, allowing the cooling plate to cool the dielectric fluid 7 in which it is immersed. This second embodiment makes it possible in particular to dispense with the presence of a fluidic connection 17 between the first heat exchanger 11 and the cooling plate 15, which can simplify the circuit.

In this second embodiment, a thermal interface may be arranged between the first heat exchanger 11 and the cooling plate 15. This embodiment is not shown in the figures. This thermal interface may in particular be made of graphite and/or a thermal paste. Using such a thermal interface between the heat exchanger and the cooling plate 15 makes it possible to increase heat transfer and thus limit heat losses. Other types of thermal interfaces may be considered.

For all the embodiments described above, the first heat exchanger 11 and/or the second heat exchanger 13 may be manufactured by additive manufacturing. Additive manufacturing makes it easy to add surface extensions to the first heat exchanger 11 and/or to the second heat exchanger 13. Additive manufacturing generally allows greater freedom in the design of parts and makes it possible to create complex shapes.

According to another embodiment shown in particular in FIG. 4, the second heat exchanger 13 of the cooling device 10 is coupled to at least one of the electronic components 5 intended to be bathed in the dielectric fluid 7. In this specific embodiment, the second heat exchanger 13 includes at least one extension 21 with an end 23 also bathed in the dielectric fluid 7 contained in the receptacle 3. This extension 21 is cooled by the second heat transfer fluid which circulates inside the second heat exchanger 13. The end 23 of this extension 21 which is bathed in the dielectric fluid 7 thus also cools the dielectric fluid 7 contained in the receptacle 3.

In a first variant of this specific embodiment, the extension 21 is cooled by conduction with the body of the second heat exchanger 13. In a second variant of this specific embodiment, the circuit for the second heat transfer fluid passes through this extension 21 at least partially immersed in the dielectric fluid 7 contained in the receptacle 3.

A method for cooling an electronic device using a cooling system 1 with a cooling device 10 according to one of the embodiments described above includes in particular the following steps:
evaporation of the second heat transfer fluid in a second heat exchanger (13);
condensation of the second heat transfer fluid in the first heat exchanger 11.

Such a method makes it possible to cool several elements using a single source, thus simplifying the circuit. In addition, the cooling power may be adapted to each of the components to be cooled.

This method may also comprise an additional step in which the first heat transfer fluid circulates in the liquid state inside the cooling plate 15 immersed in the dielectric fluid, the cooling plate 15 being thermally coupled to the first heat exchanger 11 such that heat transfer occurs between the first heat transfer fluid and the dielectric fluid.

Active circulation of the first heat transfer fluid in the liquid state inside the cooling plate 15 immersed in the dielectric fluid 7 promotes heat exchange between the cooling plate 15 and the dielectric fluid 7 contained in the receptacle 3 of the cooling system 1, thus making it possible to efficiently cool the electronic components 5 which are bathed in this same dielectric fluid 7.

This method may also comprise an additional step in which the second heat transfer fluid circulates inside the extension 21 of the second heat exchanger 13, one end 23 of the extension 21 being bathed in the dielectric fluid 7. Active circulation of the second heat transfer fluid inside the extension 21 of the second heat exchanger 13 promotes heat exchange between the end 23 of the extension 21 and the dielectric fluid 7 contained in the receptacle 3 of the cooling system 1, thus making it possible to efficiently cool the electronic components 5 which are bathed in this same dielectric fluid.

This method may also comprise an additional step in which the dielectric fluid 7 circulates around a set of electronic components 5 in order to cool them by bubbling. This circulation of the dielectric fluid 7 around the components contained in the receptacle 3 may be active, or it may be passive.

Active circulation of the dielectric fluid 7 around the electronic components 5 contained in the receptacle, for example by means of a movement means 8 for setting said dielectric fluid in motion, makes it possible to promote heat exchange and to homogenize the temperature within the dielectric fluid, thus helping to regulate the release of heat by the electronic components.

Thus, in order to homogenize the temperature of the dielectric fluid 7 in which the electronic components 5 are bathed, the cooling system 1 may in particular comprise a movement means 8 for setting said dielectric fluid 7 in motion. Such a movement means 8 for setting the dielectric fluid 7 in motion is shown in particular in FIG. 4. This movement means 8 is configured to circulate the dielectric fluid 7 contained in the receptacle 3 so as to circulate around the electronic components 5 contained in this same receptacle 3. Such circulation by a movement means 8 makes it possible to promote heat exchange and to homogenize the temperature within the dielectric fluid 7, thus making it possible to regulate the release of heat by the electronic components 5.

This movement means 8 may in particular be in the form of a pump or a propeller arranged inside the receptacle 3 which contains the dielectric fluid 7. The movement means 8 may be attached to the receptacle 3. The movement means 8 is in particular immersed in the dielectric fluid 7 contained in the receptacle 3.

The movement means 8 may comprise a spray nozzle configured to distribute the dielectric fluid 7 over some or all of the electronic components 5. Such a spray nozzle makes it possible to reach electronic components 5 which are difficult to access.

It is thus possible to design a cooling device and arrange a cooling system making it possible to cool several different elements while simplifying the circuit. This cooling device and cooling system also make it possible to adapt the cooling power to each of the components to be cooled.

What is claimed is:

1. A cooling device for a cooling system for cooling electronic components partially immersed in a dielectric fluid, comprising a first heat exchanger, the first heat exchanger configured to be partially immersed in the dielectric fluid, the first heat exchanger includes a first circuit for a first heat transfer fluid, and a second heat exchanger configured to be in contact with a portion of the electronic components, the second heat exchanger being fluidically connected to the first heat exchanger in such a way that the first heat exchanger and the second heat exchanger together form a second circuit for a second heat transfer fluid.

2. The cooling device as claimed in claim 1, wherein the first heat exchanger includes a cooling plate, the cooling plate being configured to be immersed in the dielectric fluid and thermally coupled to the first heat exchanger such that the heat produced by the immersed electrical components and transferred via the dielectric fluid to the cooling plate can be discharged via the first heat exchanger.

3. The cooling device as claimed in claim 2, wherein the first circuit for the first heat transfer fluid includes a fluidic connection between the first heat exchanger and the cooling plate, and wherein the cooling plate includes a portion of the first circuit for the first heat transfer fluid such that the first heat transfer fluid can circulate inside the cooling plate.

4. The cooling device as claimed in claim 3, wherein the fluidic connection between the first heat exchanger and the cooling plate is arranged inside the first heat exchanger and the cooling plate.

5. The cooling device as claimed in claim 3, wherein the fluidic connection is positioned outside the first heat exchanger and the cooling plate.

6. The cooling device as claimed in claim 1, wherein the second heat exchanger includes at least one extension with an end configured to be bathed in the dielectric fluid.

7. A cooling system for cooling electronic components, comprising a receptacle intended to contain electronic devices and electronic components and dielectric fluid, the electronic devices and the electronic components configured to be bathed in the dielectric fluid; and
a cooling device, the cooling device includes a first heat exchanger, the first heat exchanger configured to be partially immersed in the dielectric fluid, the first heat exchanger includes a first circuit for a first heat transfer fluid, wherein the cooling device includes a second heat exchanger configured to be in contact with a portion of the electronic components, the second heat exchanger being fluidically connected to the first heat exchanger in such a way that the first heat exchanger and the second heat exchanger together form a second circuit for a second heat transfer fluid; wherein the first heat exchanger of the cooling device is configured to be bathed at least partially in the dielectric fluid contained in the receptacle.

8. The cooling system as claimed in claim 7, further comprising a movement means for setting a fluid in motion is arranged inside the receptacle and the movement means is configured to circulate the dielectric fluid contained in the receptacle, the movement means being immersed in the dielectric fluid contained in the receptacle.

9. The cooling system as claimed in claim 7, wherein the second heat exchanger is coupled to at least one of the electronic components bathed in the dielectric-fluid.

10. (canceled)
